(19) United States
(12) Patent Application Publication
(10) Pub. No.: US 2025/0337417 A1
(43) Pub. Date: Oct. 30, 2025

(54) SIGNAL CONVERSION SYSTEM TO REDUCE ASYNCHRONOUS NOISE

(71) Applicant: TEXAS INSTRUMENTS INCORPORATED, Dallas, TX (US)

(72) Inventor: Venkat Saripalli, Bangalore (IN)

(21) Appl. No.: 18/647,725

(22) Filed: Apr. 26, 2024

(51) Int. Cl. H03L 7/089; H03L 7/093; H03L 7/099

(52) U.S. Cl. CPC H03L 7/0891; H03L 7/093; H03L 7/099

(57) ABSTRACT

Embodiments disclosed herein relate to digital signal processing, and more particularly, to reducing noise and improving performance of an analog-to-digital converter despite functioning asynchronously relative to other components of a system. In an example, a system including analog input circuitry, charge pump circuitry, and signal conversion circuitry is provided. The analog input circuitry is configured to supply an analog input signal to signal conversion circuitry. The charge pump circuitry is configured to supply a supplemental power to the analog input circuitry. The signal conversion circuitry is configured to, during each iteration of a conversion cycle: convert the analog input signal to a digital output signal and control the charge pump circuitry based on a state of the conversion cycle.

### TECHNICAL FIELD

This relates generally to digital signal processing systems.

### BACKGROUND

In electronic systems, digital signal processing components may be included to sample and convert analog signals to digital signals for use by various components of the electronic systems. To operate the digital signal processing components, an electronic system may supply the components with a supply power and with a clock signal. In various examples, such digital signal processing components include an analog-to-digital converter (ADC). ADCs may operate at various speeds to convert the analog signals to digital signals based on the frequency of the supplied clock signal. Depending on the desired sampling rate and performance of the ADC, the ADC may require a higher frequency clock signal than other components of the electronic system.

In systems that include a high-speed ADC, an existing system design may produce a high-frequency clock signal to be used by both the ADC and other components of the system. However, operating all of the components of a system at high-speeds with a high-frequency clock signal may require a high amount of power, which may increase the cost of the system design and reduce the flexibility of the system.

Alternatively, a system that includes a high-speed ADC may produce a first clock signal for the ADC at a high frequency and a second clock signal for other components at a lower frequency compared to the first clock signal frequency. However, the ADC and the other components of the system may operate asynchronously if the second clock signal does not have a frequency that is a factor of the frequency of the first clock signal. This may introduce noise into the digital signals and outputs produced by the ADC when performing conversion operations.

### SUMMARY

Various embodiments disclosed herein relate to digital signal processing, and more particularly, to controlling operations of a charge pump coupled to an analog-to-digital converter (ADC) within conversion cycles of converting analog signals to digital signals via the ADC to reduce asynchronous noise generated by the charge pump during the conversion cycles. In an example, a system including analog input circuitry, charge pump circuitry, and signal conversion circuitry is provided. The analog input circuitry is configured to supply an analog input signal to signal conversion circuitry. The charge pump circuitry is configured to supply a supplemental power to the analog input circuitry. The signal conversion circuitry is configured to, during each iteration of a conversion cycle: convert the analog input signal to a digital output signal and control the charge pump circuitry based on a state of the conversion cycle.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example system configurable to convert analog input signals to digital output signals while reducing asynchronous noise in an implementation.

FIG. 2 illustrates an example system configurable to convert analog input signals to digital output signals while reducing asynchronous noise in an implementation.

FIG. 3 illustrates an example operating environment including elements of a system configurable to convert analog input signals to digital output signals.

FIG. 4 illustrates an example charge pump circuit of a system in an implementation.

FIG. 5 illustrates an example timing diagram corresponding to elements of a system in an implementation.

FIG. 6 illustrates an example table including phases of a conversion cycle and corresponding operations thereof in an implementation.

FIG. 7 illustrates an example digital-to-analog converter (DAC) circuit used in an implementation.

FIG. 8 illustrates an example series of steps of controlling a charge pump circuit to reduce asynchronous noise in a system in an implementation.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Discussed herein are enhanced components, techniques, and systems related to analog-to-digital signal conversion and controlling supplementary power inputs via an analog-to-digital converter (ADC) for providing linearity and effective number of bits (ENOB) performance of the ADC while reducing asynchronous noise introduced by the supplementary power inputs. In a digital signal processing system, an ADC may be included to sample analog input signals and convert the analog input signals to digital output signals for use by downstream components and systems. To operate the ADC, elements of a digital signal processing system provide a supply voltage and a clock signal to the ADC. The ADC uses the clock signal to perform conversion cycles during which the ADC converts analog input signals to digital output signals. The sampling rate at which the ADC performs such conversion may be based on the frequency of the clock signal provided to the ADC.

In an example digital signal processing system, a 12-bit ADC may be implemented to perform sampling and conversion operations with a sampling rate of 4 Megasamples per second (MSPS). To achieve such a sampling rate, the ADC may be configured to perform a conversion cycle in approximately 250 nanoseconds (ns). In order to perform the conversion cycle at the sampling rate of 4 MSPS, a relatively high frequency clock signal may be required, such as a clock signal with a frequency of over 80 MHz, which may be a higher frequency clock signal compared to a system clock signal used for other elements of the digital signal processing system.

Further, supplemental power, in addition to a digital supply power (e.g., 1.35 V), may be provided to the ADC to support operation of the ADC at the desired sampling rate. In such designs, a charge pump circuit may be included in a digital signal processing system to provide the supplemental power to the ADC. However, the charge pump circuitry may operate using a different frequency clock signal relative to the ADC, such as with a clock signal having a frequency of 32 MHz (i.e., the system clock signal). Problematically, the conversion clock signal (e.g., 80 MHZ) and the charge pump clock signal (e.g., 32 MHz) may be asynchronous relative to one another, which may cause the ADC and the charge pump circuitry to function asynchronously. This lack of synchronicity may introduce noise to the ADC and affect linearity and ENOB of the ADC. Although an ADC may include noise correction capabilities during some portions of a conversion cycle, existing ADCs might not have correction capabilities during other, less noise sensitive, portions of the conversion cycle, such as during an end portion of the conversion cycle.

As disclosed herein, a system can implement charge pump control techniques and methods to operate a 12-bit ADC at 4 MSPS with reduced amounts of noise caused by asynchronous operations based on differing clock signals. As the ADC of the system operates in a portion of the conversion cycle, the ADC can be configured to control the charge pump circuitry. More specifically, the ADC may be configured to output a signal to gate the system clock signal from being supplied to the charge pump circuitry.

Advantageously, the ADC can operate at a desired sampling rate with various numbers of analog inputs with a reduction in noise introduced by the charge pump circuitry as the charge pump circuitry can be controlled (i.e., turned on or off) during portions of conversion cycles of the ADC. This may not only improve the linearity and ENOB performance of the ADC but also conserve power in the system as the charge pump circuitry may be disabled or enabled throughout operations of the ADC.

In an example, a system including analog input circuitry, charge pump circuitry, and signal conversion circuitry is provided. The analog input circuitry is configured to supply an analog input signal to signal conversion circuitry. The charge pump circuitry is configured to supply a supplemental power to the analog input circuitry. The signal conversion circuitry is configured to, during each iteration of a conversion cycle: convert the analog input signal to a digital output signal and control the charge pump circuitry based on a state of the conversion cycle.

In another example, a system is provided. The system includes analog input circuitry, charge pump circuitry, and signal conversion circuitry. The analog input circuitry is configured to supply an analog input signal to signal conversion circuitry. The charge pump circuitry is configured to supply a supplemental power to the analog input circuitry. The signal conversion circuitry includes a digital-to-analog converter coupled to receive the analog input signal from the analog input circuitry, a comparator coupled to the digital-to-analog converter, and a successive-approximation-register converter coupled to the digital-to-analog converter and to the comparator. The signal conversion circuitry is configured to, during each iteration of a conversion cycle: convert the analog input signal to a digital output signal and control the charge pump circuitry based on a state of the conversion cycle.

In yet another example, a method of controlling charge pump circuitry to reduce asynchronous noise is provided. The method includes receiving, via analog input circuitry, an analog input signal for conversion to a digital output signal during a conversion cycle, supplying, via charge pump circuitry, supplemental power to the analog input circuitry, and during each iteration of the conversion cycle: converting, via signal conversion circuitry, the analog input signal to the digital output signal and controlling, via the signal conversion circuitry, the charge pump circuitry based on a state of the conversion cycle.

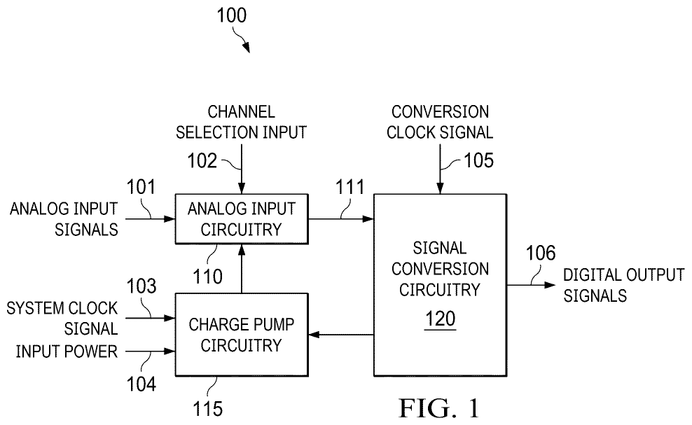

FIG. 1 illustrates an example system configurable to convert analog input signals to digital output signals while reducing asynchronous noise in an implementation. FIG. 1 shows system 100, which includes analog input circuitry 110, charge pump circuitry 115, and signal conversion circuitry 120. Analog input circuitry 110 may be configured to receive analog input signals 101 and channel selection input 102. Charge pump circuitry 115 may be configured to receive system clock signal 103 and input power 104. Signal conversion circuitry 120 may be configured to receive conversion clock signal 105 and output digital output signals 106.

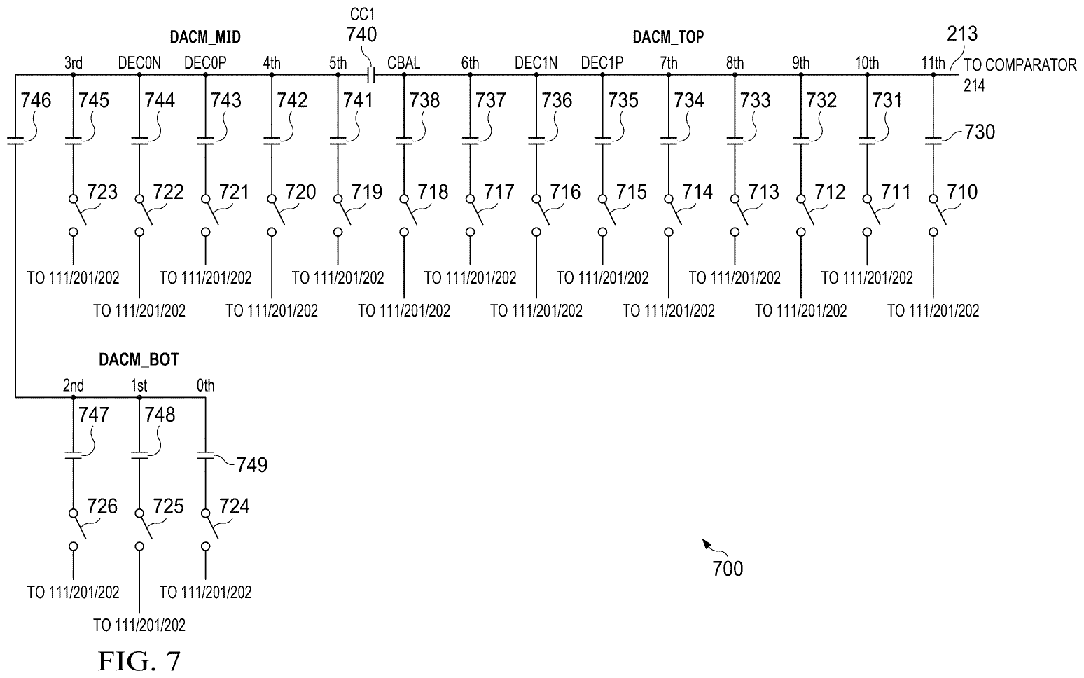

In various examples, system 100 may be representative of a digital signal processing system capable of receiving analog input signals 101, converting analog input signals 101 at a desired sampling rate, and producing digital output signals 106. As such, elements of system 100 may include dedicated, fixed-purpose hardware components capable of performing sampling and conversion operations and charge pump control operations, such as operations 700 of FIG. 7. System 100 may be embodied in circuitry utilized in an embedded system or system-on-chip (SoC), such as a microcontroller unit (MCU). In an example, system 100 may include other elements that produce inputs to elements of system 100 and provide such inputs to respective elements (e.g., a system clock generation circuit).

Analog input circuitry 110 may be representative of one or more components capable of receiving analog input signals 101, receiving channel selection input 102, selecting one or more of analog input signals 101 based on channel selection input 102, and outputting selected signals to signal conversion circuitry 120 for sampling and conversion to digital output signals 106. In various examples, analog input circuitry 110 may include a multiplexer configured to select an analog input signal 111, of analog signals 101, to convert based on channel selection input 102. Channel selection input 102 may be provided to analog input circuitry 110 by a circuit, a processor (e.g., a central processing unit (CPU)), or by some other peripheral.

Analog input circuitry 110 may also be coupled to receive supplemental power from charge pump circuitry 115. Charge pump circuitry 115 may be representative of a circuit capable of receiving system clock signal 103 and input power 104 and producing a supplemental power based on system clock signal 103 and input power 104 that may have a higher voltage than input power 104. For example, input power 104 may be a power supply voltage of system 100, which has a voltage value of approximately 1.35 V, and system clock signal 103 may be a clock signal used by various elements of system 100, which has a frequency value of 32 MHz during run-time operation of system 100. Charge pump circuitry 115 can operate according to system clock signal 103 and produce a supplemental power having a voltage value of approximately 3 V. Charge pump circuitry 115 can supply this supplemental power to analog input circuitry 110 to power elements of analog input circuitry 110 and signal conversion circuitry 120 (e.g., transistors).

Signal conversion circuitry 120 may be representative of an analog-to-digital converter (ADC) capable of receiving analog signal 111 (i.e., an analog signal to convert from among the analog input signals 101) from analog input circuitry 110 and converting the analog signal 111 to a respective digital output signal 106 based on conversion clock signal 105 and by using the supplemental power generated by charge pump circuitry 115. In various examples, signal conversion circuitry 120 includes a capacitive digital-to-analog converter (CDAC), a comparator, and a successive-approximation register (SAR) ADC, among other components. Together, these components can sample values of the analog input signals 105 at a sampling rate based on conversion clock signal 105 to produce digital output signals 106.

In an example, signal conversion circuitry 120 is representative of a 12-bit ADC configured to operate with a sampling rate of 4 Megasamples per second (MSPS). Accordingly, conversion clock signal 105 may include a clock signal having a frequency of approximately 80 MHz. Based on this sampling rate, signal conversion circuitry 120 may be configured to perform a single conversion cycle in approximately 250 ns. A conversion cycle may include a sampling period and a conversion period. The conversion period may have 14 sub-cycles, which include 12 sub-cycles based on 12 bits and 2 error-correction sub-cycles. The 2 error-correction sub-cycles may be included to perform noise correction operations. Signal conversion circuitry 120 may be configured to perform the sampling period in approximately 62.5 ns and the conversion period in approximately 187.5 ns.

During each conversion cycle, signal conversion circuitry 120 may be configured to control charge pump circuitry 115 based on a state of the conversion cycle. More specifically, signal conversion circuitry 120 may be configured to disable or enable charge pump circuitry 115, such as by gating system clock signal 103 from being provided to charge pump circuitry 115. This may entail outputting a signal to charge pump circuitry 115 or to clock gating circuitry coupled to charge pump circuitry 115 that gates system clock signal 103 from being received by charge pump circuitry 115. In this way, charge pump circuitry 115 would not provide the supplemental power, or recalibrate the supplemental power, to analog input circuitry 110 and signal conversion circuitry 120 as charge pump circuitry 115 would not receive system clock signal 103, which may reduce noise injected into signal conversion circuitry 120.

To control charge pump circuitry 115, signal conversion circuitry 120 may be configured to identify a portion of the conversion cycle in which to disable the charge pump circuitry 115 (e.g., based on a count of clock cycles during the conversion cycle exceeding a threshold that indicates the transition from a portion with error correction portion to a portion without error correction), determine that the count of clock cycles exceeds a threshold clock cycle, and disable charge pump circuitry 115 during the identified portion. Following the example above where the conversion cycle includes 14 sub-cycles during a conversion period, the threshold clock cycle may be determined as a sub-cycle immediately following a second one of the error-correction sub-cycles because the portion after the second error-correction sub-cycle (e.g., sub-cycles 3 to 0) might not have any error-correction and may thus be more affected by noise. Accordingly, signal conversion circuitry 120 may be configured to disable charge pump circuitry 115 in response to detecting that signal conversion circuitry 120 is in a portion of a conversion cycle that lacks other noise mitigation (i.e., conversion clock signal 105 has reached a number of cycles corresponding to a functional, or non-error-correction, state). Following completion of a conversion cycle and/or at the initiation of a subsequent conversion cycle, signal conversion circuitry 120 may be configured to enable, or re-enable, charge pump circuitry 115, such as by outputting a second signal to charge pump circuitry 115, or clock gating circuitry coupled thereto, to allow system clock signal 103 to be provided to charge pump circuitry 115.

In operation, analog input circuitry 110 receives channel selection input 102 indicating one of analog input signals 101 for processing. Analog input circuitry 110 can provide the selected analog input signal 111 to signal conversion circuitry 120. Charge pump circuitry 115 may turn on based on receiving system clock signal 103 and input power 104 and provide the supplemental power to analog input circuitry 110 and signal conversion circuitry 120. When signal conversion circuitry 120 receives the selected analog input signals and conversion clock signal 105, signal conversion circuitry 120 can convert the selected analog input signals to digital signals over one or more conversion cycles based on conversion clock signal 105. However, based on charge pump circuitry 115 operating according to system clock signal 103 and signal conversion circuitry 120 operating according to conversion clock signal 105, which both have different frequencies that are not a factor of one another, charge pump circuitry 115 and signal conversion circuitry 120 may operate asynchronously with respect to each other creating noise in the digital signals as signal conversion circuitry 120 converts the selected analog signals. During the conversion cycle, signal conversion circuitry 120 can identify the state of the conversion cycle and disable charge pump circuitry 115 for the remainder of the conversion cycle, such that charge pump circuitry 115 stops producing the supplemental power (i.e., stops recalibrating the supplemental power), which reduces the noise produced when converting the analog input signals. Signal conversion circuitry 120 can complete the conversion cycle without supplemental power from charge pump circuitry 115, produce digital output signals 106 from the selected analog input signals, and provide digital output signals 106 downstream to another system, sub-system, circuit, or the like.

In some examples, elements of system 100 may include fewer, additional, or different components. For example, signal conversion circuitry 120 may include a different type of ADC, charge pump circuitry 115 may include additional or fewer stages, which may be configured to produce a different amount of supplemental power, and the like. Furthermore, signal conversion circuitry 120 may operate at a different sampling rate or using a different number of bits. Regardless, signal conversion circuitry 120 may be configured to disable and/or enable charge pump circuitry 115 before, during, and/or after a conversion period based on conversion clock signal 105, the type of ADC, and the number of bits, among other factors.

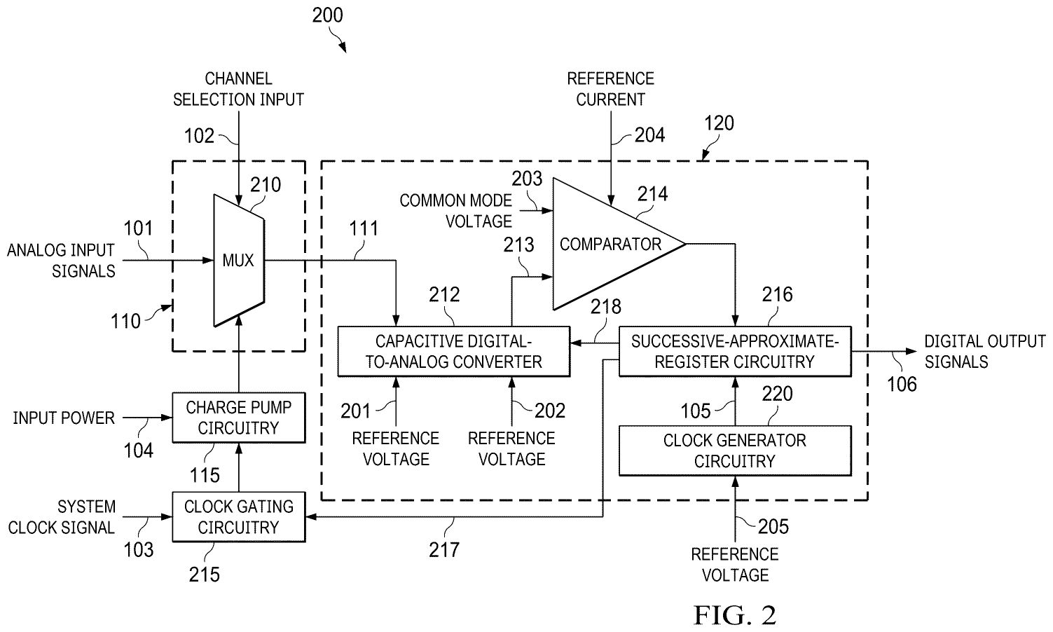

FIG. 2 illustrates an example system configurable to convert analog input signals to digital output signals while reducing asynchronous noise in an implementation. FIG. 2 shows system 200, which includes analog input circuitry 110, charge pump circuitry 115, signal conversion circuitry 120, and clock gating circuitry 215. Analog input circuitry 110 includes multiplexer 210. Signal conversion circuitry 120 includes capacitive digital-to-analog converter (CDAC) 212, comparator 214, successive-approximation-register (SAR) circuitry 216, and clock generator circuitry 220.

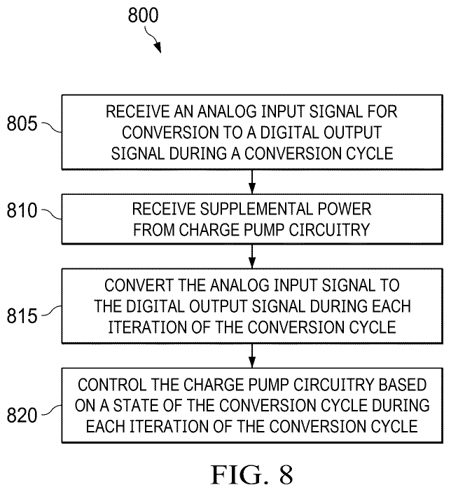

In various examples, system 200 may be representative of a digital signal processing system capable of receiving analog input signals 101, converting analog input signals 101 at a desired sampling rate, and producing digital output signals 106. As such, elements of system 200 may include dedicated, fixed-purpose hardware components capable of performing sampling and conversion operations and charge pump control operations, such as operations 800 of FIG. 8. System 200 may be embodied in circuitry utilized in an embedded system or system-on-chip (SoC), such as a microcontroller unit (MCU). In an example, system 200 may include other elements that produce inputs to elements of system 200 and provide such inputs to respective elements.

Analog input circuitry 110 may be representative of one or more components capable of receiving analog input signals 101, receiving channel selection input 102, selecting one or more of analog input signals 101 based on channel selection input 102, and outputting the selected signal(s) 111 to signal conversion circuitry 120 for sampling and conversion to digital output signals 106. In various examples, analog input circuitry 110 includes multiplexer 210 configured to select an analog input signal based on channel selection input 102. Channel selection input 102 may be provided to analog input circuitry 110 by a circuit, a processor (e.g., a central processing unit (CPU)), or by some other peripheral.

Analog input circuitry 110 may also be coupled to receive supplemental power from charge pump circuitry 115. Charge pump circuitry 115 may be representative of a circuit capable of receiving system clock signal 103 from clock gating circuitry 215, receiving input power 104 from a power supply, and producing a supplemental power based on system clock signal 103 and input power 104 that may have a higher voltage than input power 104. For example, input power 104 may be a voltage produced and supplied by a power supply of system 200, which has a voltage value of approximately 1.35 V.

Clock gating circuitry 215 may be representative of one or more circuits or components capable of receiving system clock signal 103 and control signals 217 from SAR circuitry 216 and either providing system clock signal 103 to charge pump circuitry 115 or gating system clock signal 103 from charge pump circuitry 115 based on control signals 217. In various examples, clock gating circuitry 215 may include one or more digital logic components, such as an AND gate, that can supply or gate system clock signal 103 based on control signals 217 and system clock signal 103.

System clock signal 103 may be a clock signal used by various elements of system 200, which has a frequency value of 32 MHz during run-time operation of system 200. When supplied with system clock signal 103, charge pump circuitry 115 can operate according to system clock signal 103 and produce a supplemental power having a voltage value of approximately 3 V. Charge pump circuitry 115 can supply this supplemental power to analog input circuitry 110 to power multiplexer 210 of analog input circuitry 110 and CDAC 212 of signal conversion circuitry 120.

Signal conversion circuitry 120 may be representative of an analog-to-digital converter (ADC) capable of receiving analog input signals 101 from analog input circuitry 110 and converting analog input signals 101 to digital output signals 106 based on conversion clock signal 105 and by using the supplemental power generated by charge pump circuitry 115. In various examples, signal conversion circuitry 120 includes CDAC 212, comparator 214, SAR circuitry 216, and clock generator circuitry 220. Together, these components can sample values of the analog input signals 105 at a sampling rate based on conversion clock signal 105 to produce digital output signals 106.

CDAC 212 may include various components capable of generating binary weighted voltages (e.g., analog input 213) as a function of a digital value 218 from SAR circuitry 216 and the reference input (e.g., an analog input signal bit) as part of the sampling and conversion operations. In various examples, CDAC 212 may include a number of switches, or transistors, configured to receive a reference voltage (e.g., reference voltage 201, reference voltage 202), supplemental power from charge pump circuitry 115, and analog input signals 101 and provide a weighted voltage based the digital value 218 to comparator 214.

Comparator 214 may be included to perform bit decision-making with respect to sampling and conversion operations. Comparator 214 may be coupled to receive an common mode voltage 203 (i.e., from a power supply), the weighted voltage from CDAC 212, analog input 213, and reference current 204. In operation, comparator 214 may be configured to perform a comparison between a value of common mode voltage 203 and a value of analog input 213 (i.e., the weighted voltage) provided by CDAC 212 to generate a result. Comparator 214 may further be coupled to SAR circuitry 216 and provide results to SAR circuitry 216.

SAR circuitry 216 may be configured to perform one or more algorithms to sample and convert analog input signals 101 to digital output signals 106 based on conversion clock signal 105 provided by clock generator circuitry 220. Clock generator circuitry 220 may be representative of a clock generation circuit that is coupled to receive reference voltage 205 (e.g., a 1.25 V signal from a bandgap reference circuit) and produce conversion clock signal 105. In various examples, clock generator circuitry 220 is configured to produce conversion clock signal 105 having a frequency of 80 MHz. In such examples, SAR circuitry 216 is representative of a 12-bit SAR ADC configured to operate with a sampling rate of 4 Megasamples per second (MSPS) using conversion clock signal 105. Based on this sampling rate, SAR circuitry 216 may be configured to perform a single conversion cycle in approximately 250 ns. A conversion cycle may include a sampling period and a conversion period. The conversion period may have 14 sub-cycles, which include 12 sub-cycles used to determine 12 bits of the digital output signal 106 and 2 error-correction sub-cycles used to confirm various bits of the digital output signal 106. The 2 error-correction sub-cycles may be included to perform noise correction operations. SAR circuitry 216 may be configured to perform the sampling period in approximately 62.5 ns and the conversion period in approximately 187.5 ns.

During each conversion cycle, SAR circuitry 216 may be configured to control charge pump circuitry 115 based on a state of the conversion cycle via clock gating circuitry 215. More specifically, SAR circuitry 216 may be configured to provide control signals 217 to clock gating circuitry 215 to disable or enable charge pump circuitry 115, such as by gating system clock signal 103 from being provided to charge pump circuitry 115. For example, based on a first state of the conversion cycle, SAR circuitry 216 can provide control signals 217 having a first value indicative of a logical high state to clock gating circuitry 215. Based on control signals 217 including a logical high value, clock gating circuitry 215 can provide system clock signal 103 to charge pump circuitry 115 to enable operation thereof. Based on a second state of the conversion cycle, SAR circuitry 216 can provide control signals 217 having a second value indicative of a logical low state to clock gating circuitry 215. Based on control signals 217 including a logical low value, clock gating circuitry 215 can gate system clock signal 103, such that charge pump circuitry 115 does not receive system clock signal 103, and thus, does not produce recalibrated supplemental power for analog input circuitry 110 and signal conversion circuitry 120.

To control charge pump circuitry 115, SAR circuitry 216 may be configured to identify a count of clock cycles of conversion clock signal 105 during the conversion cycle, determine that the count of clock cycles exceeds a threshold clock cycle, and in response to determining that the count of clock cycles exceeds the threshold clock cycle, disable charge pump circuitry 115 via control signals 217 provided to clock gating circuitry 215. Following the example above where the conversion cycle includes 14 sub-cycles during a conversion period, a first error-correction sub-cycle is used to perform error correction on a first subset of the digital bits of output signal 106, a second error-correction sub-cycle is used to perform error correction on a second subset of the digital bits of output signal 106, and a third subset of the digital bits of output signal 106 do not have any associated error correction. In this example, the threshold clock cycle may be determined as a sub-cycle immediately following a second one of the error-correction sub-cycles. The remaining portion of sub-cycles following this error-correction sub-cycle may include functional sub-cycles at the end of the conversion period (e.g., sub-cycles 3 to 0). Accordingly, SAR circuitry 216 may be configured to disable charge pump circuitry 115 in response to detecting that SAR circuitry 216 is in a functional state of a conversion cycle (i.e., conversion clock signal 105 has reached a number of cycles corresponding to a functional state) by providing control signals 217 to clock gating circuitry 215 that causes clock gating circuitry 215 to gate system clock signal 103 from being provided to charge pump circuitry 115. Following completion of a conversion cycle and/or at the initiation of a subsequent conversion cycle, SAR circuitry 216 may be configured to enable, or re-enable, charge pump circuitry 115, such as by outputting control signals 217 with a different value to clock gating circuitry 215, which causes clock gating circuitry 215 to provide system clock signal 103 to charge pump circuitry 115.

In some examples, elements of system 200 may include fewer, additional, or different components. For example, signal conversion circuitry 120 may include a different type of ADC, charge pump circuitry 115 may include additional or fewer stages, which may be configured to produce a different amount of supplemental power, and the like. Furthermore, signal conversion circuitry 120 may operate at a different sampling rate or using a different number of bits. Regardless, signal conversion circuitry 120 may be configured to disable and/or enable charge pump circuitry 115 before, during, and/or after a conversion period based on conversion clock signal 105, the type of ADC, and the number of bits, among other factors.

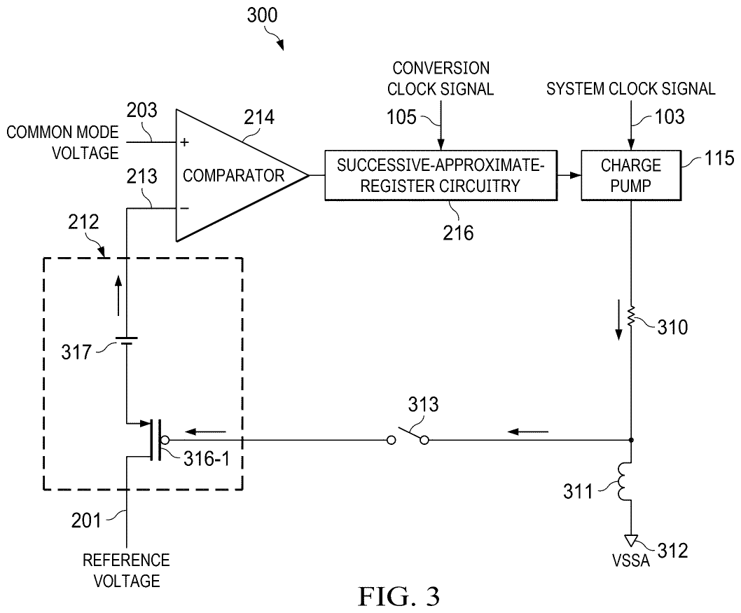

FIG. 3 illustrates an example operating environment including elements of a system configurable to convert analog input signals to digital output signals. FIG. 3 shows operating environment 300, which includes charge pump 115, resistor 310, inductor 311, ground node 312, switch 313, CDAC 212, comparator 214, and SAR circuitry 216. CDAC 212 may include transistor 316-1 and capacitor 317.

In operating environment 300, charge pump circuitry 115 may be coupled to receive system clock signal 103 and may be coupled to a first terminal of resistor 310. Resistor 310 may include a second terminal coupled to a first terminal of inductor 311 and to switch 313. Inductor 311 may include a second terminal coupled to ground node 312. Switch 313 may be coupled to CDAC 212. CDAC 212 may include a plurality of transistors (e.g., transistor 316-1) and capacitors (e.g., capacitor 317). Each transistor may include a gate terminal, a drain terminal, and a source terminal. Capacitor 317 may include a first terminal and a second terminal. Thus, switch 313 may be coupled to the gate terminal of transistor 316-1 of CDAC 212. The drain terminal of transistor 316-1 may be coupled to receive reference voltage 201, and the source terminal of transistor 316-1 may be coupled to the first terminal of capacitor 317 of CDAC. The second terminal of capacitor 317 may be coupled to a first input of comparator 214. Comparator 214 may include a second input coupled to receive common mode voltage 203 and an output coupled to SAR circuitry 216.

In operation, charge pump circuitry 115 may be configured to receive system clock signal 103 to generate and supply a supplemental power, which produces noise through elements, such as resistor 310, to ground node 312. More specifically, charge pump circuitry 115 may provide the supplemental power to drive transistors of CDAC 212, such as transistor 316-1. CDAC 212 may be configured to operate using reference voltage 201 and the supplemental power and provide voltage values as inputs to comparator 214, such as analog input 213. Comparator 214 performs a comparison between common mode voltage 203 and the voltage outputs from CDAC 212 (e.g., analog input 213) and provides outputs to SAR circuitry 216. SAR circuitry 216 may be configured to receive conversion clock signal 105 to generate digital output signals in accordance with a sampling rate based on conversion clock signal 105.

Problematically, system clock signal 103 and conversion clock signal 105 may be asynchronous. As CDAC 212 operates and provides inputs to comparator 214, and comparator 214 provides outputs to SAR circuitry 216, the supplemental power creating noise at ground node 312, which drives CDAC 212, may introduce noise into the digital output signals generated by SAR circuitry 216. The effect of this noise may increase as the number of analog input samples and the number of sampling requests increases. While only one transistor (transistor 316-1) and one path between charge pump circuitry 115 and CDAC 212 is shown in operating environment 300, CDAC 212 may include one or more other transistors that can each include a gate terminal coupled to be driven by the supplemental power from charge pump circuitry 115 via ground node 312 (shown and described in FIG. 7). Each transistor, or switch, of CDAC 212 may be used for a different conversion sub-cycle corresponding to different bits of analog input signals 101. It follows that the power at ground node 312 may drive each of these transistors, and as higher numbers of analog input signals are provided to CDAC 212 for sampling and conversion to digital output signals via CDAC 212, comparator 214, and SAR circuitry 216, more noise may be introduced to CDAC 212 caused by the supplemental power created by charge pump circuitry 115.

To reduce this noise, SAR circuitry 216 may be configured to control charge pump circuitry 115 based on a state of a conversion cycle. More specifically, SAR circuitry 216 may be configured to disable or enable charge pump circuitry 115. For example, based on a first state of the conversion cycle, SAR circuitry 216 can provide a signal (e.g., control signals 217) to prevent charge pump circuitry 115 from receiving system clock signal 103, such that charge pump circuitry 115 does not produce recalibrated supplemental power driven to ground node 312, and in turn, supplied to CDAC 212, and thus, may avoid injecting noise into CDAC 212 via ground node 312.

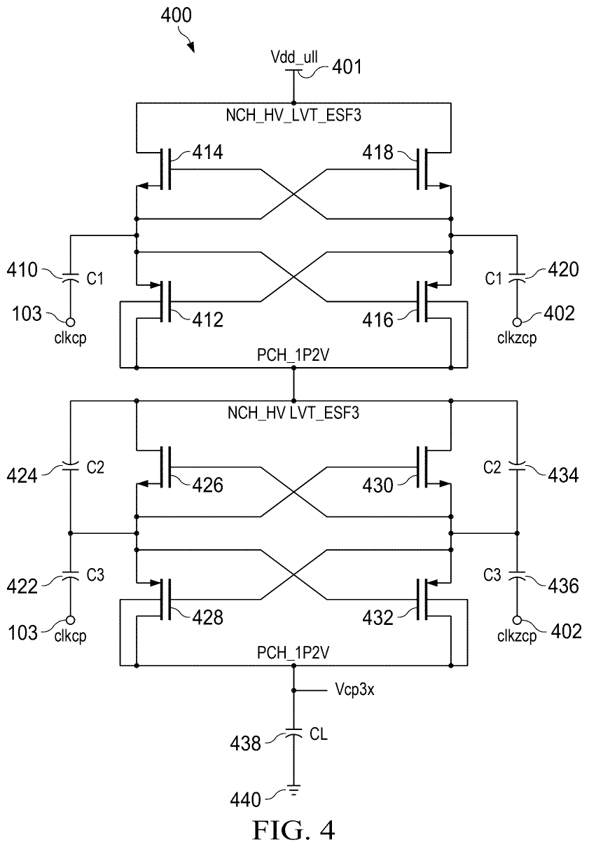

FIG. 4 illustrates an example charge pump circuit of a system in an implementation. FIG. 4 shows charge pump 400, which includes two stages of capacitors and transistors, and which may be configured to provide a supplemental power to components of a digital signal processing system, such as analog input circuitry 110 and signal conversion circuitry 120 of systems 100 and 200.

Charge pump 400 has a first stage that includes capacitor 410, transistors 412, 414, 416, and 418, and capacitor 420 and a second stage that includes capacitors 422, 424, 434, 436, and 438 and transistors 426, 428, 430, and 432. The first stage may be coupled to receive system clock signal 103, inverted system clock signal 402, and input power 401 and may be coupled to the second stage. The second stage may be coupled to receive system clock signal 103 and inverted clock signal 402 and may be coupled to ground node 440. Each of the capacitors of charge pump 400 includes a first terminal and a second terminal. Each of the transistors of charge pump 400 includes a gate terminal, a source terminal, and a drain terminal.

In the first stage, the first terminal of capacitor 410 is coupled to receive system clock signal 103, and the second terminal of capacitor 410 is coupled to the source terminal of transistor 412 and to the source terminal of transistor 414. The drain terminal of transistor 414 is coupled to the drain terminal of transistor 418, which are both coupled to receive input power 401. The gate terminal of transistor 414 is coupled to the source terminal of transistor 418, while the gate terminal of transistor 418 is coupled to the source terminal of transistor 414. The source terminal of transistor 418 is also coupled to the source terminal of transistor 416, which are both coupled to the first terminal of capacitor 420. The second terminal of capacitor 420 is coupled to receive inverted system clock signal 402 (i.e., an inverted version of system clock signal 103). The source terminals of transistors 416 and 418 are further coupled to the gate terminal of transistor 412. The gate terminal of transistor 416 is coupled to the drain terminal of transistor 412. The drain terminals of transistors 412 and 416 are coupled together and are coupled to the second stage of charge pump 400.

In the second stage, the first terminal of capacitor 422 is coupled to receive system clock signal 103, and the second terminal of capacitor 422 is coupled to the first terminal of capacitor 424 and to the source terminals of transistors 426 and 428. The second terminal of capacitor 424 is coupled to the drain terminals of transistors 426 and 430, which are all further coupled to the first stage of charge pump 400 and to the first terminal of capacitor 434. The second terminal of capacitor 434 is coupled to the first terminal of capacitor 436, which are both coupled to the source terminals of transistors 430 and 432. The second terminal of capacitor 436 is coupled to receive inverted system clock signal 402.

The gate of transistor 426 is coupled to the source of transistor 430. The gate of transistor 430 is coupled to the source terminal of transistor 426. The gate terminal of transistor 428 is coupled to the source terminals of transistors 430 and 432. The gate terminal of transistor 432 is coupled to the source terminal of transistor 428. The drain terminal of transistor 428 is coupled to the drain terminal of transistor 432, which are both further coupled to the first terminal of capacitor 438. The second terminal of capacitor 438 is coupled to ground node 440.

In other examples, charge pump 400 may include fewer, additional, or different components. For example, charge pump 400 may include additional stages to increase input power 401 to a higher voltage value or fewer stages to generate a lower voltage value.

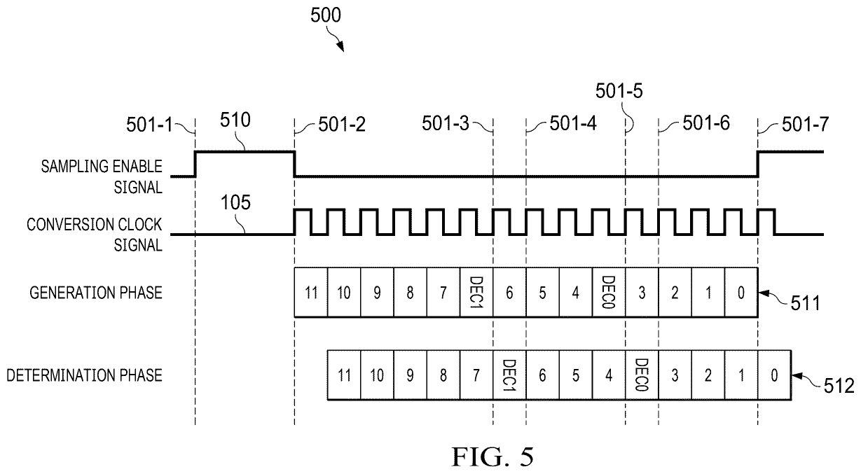

FIG. 5 illustrates an example timing diagram corresponding to elements of a system in an implementation. FIG. 5 shows timing diagram 500, which includes example logical state values output by components of a system (e.g., system 100 of FIG. 1, system 200 of FIG. 2) at different times during sampling and conversion operations. The state values demonstrated by timing diagram 500 may be illustrated as high signals (“1” or “on”) or low signals (“0” or “off”).

Timing diagram 500 includes logical state values corresponding to sampling enable signal 510 and conversion clock signal 105 relative to generation phase 511 and determination phase 512. More particularly, sampling enable signal 510 may be representative of a signal that, when in a logical high state, enables signal conversion circuitry 120 to perform sampling operations on a selected one of the analog input signals 101 (e.g., analog signal 111), and when in a logical low state, enables signal conversion circuitry 120 to hold the sampled voltage value by providing a corresponding analog signal for conversion that has the sampled voltage value. Conversion clock signal 105 may be representative of a clock signal at a frequency to enable conversion operations at a given sampling rate. Signal conversion circuitry 120 may use conversion clock signal 105 to perform such conversion operations over a conversion cycle. The duration of or the number of sub-cycles within the conversion cycle may be based on the characteristics of signal conversion circuitry 120, or more specifically, SAR circuitry 216 of signal conversion circuitry 120.

In an example, SAR circuitry 216 is representative of a 12-bit ADC configured to operate with a sampling rate of 4 Megasamples per second (MSPS). Accordingly, conversion clock signal 105 may include a clock signal having a frequency of approximately 80 MHz. A conversion cycle may include a sampling period and a conversion period. The conversion period may have 14 sub-cycles, which include 12 sub-cycles based on 12 bits and 2 error-correction sub-cycles. Generation phase 511 represents the generation of an analog input to the comparator 214 associated with the specified bit or error correction in a particular sub-cycle, and determination phase 512 represents the use of the output of the comparator 214 to determine the specified bit or error correction in a particular sub-cycle. Generation phase 511 and determination phase 512 both include a number of sub-cycles. The sub-cycles of determination phase 512 may occur one clock cycle after the sub-cycles of generation phase 511. The 2 error-correction sub-cycles (denoted by DEC1 and DEC0 in in both generation phase 511 and determination phase 512) may be included to perform noise correction operations. Signal conversion circuitry 120 may be configured to perform the sampling period in approximately 62.5 ns and the conversion period in approximately 187.5 ns.

With respect to timing diagram 500, the sampling period may occur between time 501-1 and time 501-2, such as when sampling enable signal 510 is in a logical high state, and the conversion period may occur between time 501-2 and time 501-7 when sampling enable signal 510 is in a logical low state. Accordingly, when sampling enable signal 510 transitions from the logical high state to the logical low state, conversion clock signal 105 may transition from the logical low state to the logical high state and continue to transition between each state with a duty cycle corresponding to the frequency of conversion clock signal 105.

Between time 501-2 and time 501-3, analog inputs are generated during generation sub-cycles 11 through 7 of generation phase 511, and an error-correction input during an error-correction sub-cycle (DEC 1) is generated. Between these times, conversion clock signal 105 transitions between each state 5 times, which corresponds to determination sub-cycles 11 through 7, of determination phase 512, of the conversion period bits 11-7 of the digital value (e.g., digital value 218). The first determination sub-cycle (sub-cycle 11) may determine the most significant bit of the corresponding digital value (e.g., bit 11), the second determination sub-cycle (sub-cycle 10) may determine the next most significant bit of the corresponding digital value (e.g., bit 10), and so on. Between time 501-3 and time 501-4, signal conversion circuitry 120 performs an error-correction cycle (denoted by DEC1 in timing diagram 500) during which signal conversion circuitry 120 can perform noise correction operations with an accuracy of up to 64 least-significant-bits (LSBs) of data processed during sub-cycles 11 through 7. Also at this time, an analog input is generated for generation sub-cycle 6. Between time 501-4 and time 501-5, analog inputs are generated during generation sub-cycles 5 through 4 of generation phase 511, and an error-correction input during an error-correction sub-cycle (DEC 0) is generated. Between these times, conversion clock signal 105 transitions between each state 3 times, which corresponds to determination sub-cycles 6 through 4 of the conversion period and bits 6-4 of the digital value. At or before time 501-5, signal conversion circuitry 120 may be configured to control charge pump circuitry 115 to reduce noise for the remainder of the sub-cycles. Between time 501-5 and 501-6, signal conversion circuitry 120 performs a second error-correction cycle (denoted by DECO in timing diagram 500) during which signal conversion circuitry 120 performs additional noise correction operations with an accuracy of up to 8 LSBs of data processed during sub-cycles 6 through 4. Between time 501-6 and 501-7, analog inputs are generated during generation sub-cycles 2 through 0 of generation phase 511, and conversion clock signal 105 transitions between each state 4 times until time 501-7 when sampling enable signal 510 transitions from the low logical state to the high logical state. These 4 transitions correspond to determination sub-cycles 3 through 0 and bits 3-0 of the digital value. Due to time or other factors, signal conversion circuitry 120 might not perform noise correction operations with respect to these least significant bits. Accordingly, these sub-cycles are referred to as functional, or non-error-correction, sub-cycles. During this portion of the conversion cycle, charge pump circuitry 115 may continue to be disabled, which may reduce noise given the lack of noise correction capabilities during the non-error-correction sub-cycles (e.g., determination sub-cycles 3 through 0).

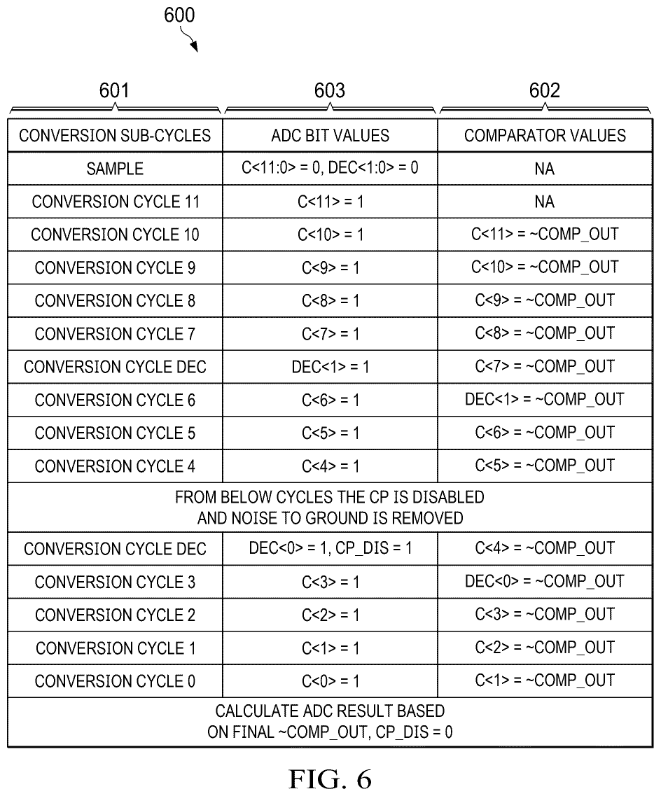

FIG. 6 illustrates an example table including phases of a conversion cycle and corresponding operations thereof in an implementation. FIG. 6 shows table 600, which includes example conversion sub-cycles 601, comparator values 602, and ADC bit values generated 603 corresponding to a system including a 12-bit SAR ADC operating at a sampling rate of 4 MSPS (e.g., system 100 of FIG. 1, system 200 of FIG. 2).

Conversion sub-cycles 601 may include a set of cycles during which the SAR ADC (e.g., SAR circuitry 216) performs sampling and/or conversion operations. The duration of each conversion cycle may be based on the frequency of a clock signal used by the SAR ADC (e.g., conversion clock signal 105). In an example, the SAR ADC performs a first number of cycles followed by a first error-correction cycle (e.g., DEC1), a second number of cycles followed by a second error-correction cycle (e.g., DEC0), and a third number of cycles to generate digital output signals (e.g., digital output signals 106) from analog input signals (e.g., analog input signals 101).

In various examples, the system includes a CDAC (CDAC 212) and a comparator (e.g., comparator 214) as part of to the SAR ADC. The CDAC 212 generates an analog input value (e.g., a voltage) (e.g., analog input 213) for comparison by the comparator 214 for the indicated ADC bit values 603. In the subsequent sub-cycle, the output of the comparator 214 is used to determine the corresponding bit value, a respective one of comparator values 602, associated with the analog input voltage.

Referring to table 600, a sampling sub-cycle of conversion sub-cycles 601 may be the first part of the sampling and conversion process. During this period, the CDAC of the system may obtain samples of the analog input signals prior to conversion of the analog input signals to the digital output signals. Accordingly, there might not be any comparator values 602, and ADC bit values 603 may include a value of 0.

Following the sampling sub-cycle, the SAR ADC may begin performing conversion sub-cycles to convert the analog input signals to digital output signals. A first conversion sub-cycle may be referred to as conversion sub-cycle 11. At conversion sub-cycle 11, the CDAC generates a first analog value of ADC bit values 603. A second conversion sub-cycle may be referred to as conversion sub-cycle 10 during which the first analog value from conversion sub-cycle 11 is supplied to the comparator. The comparator can perform a comparison and output a result (denoted by “COMP_OUT”) to the SAR ADC to be stored as a 1/0 as shown in table 600 under comparator values 602. At conversion sub-cycle 10, the CDAC generates a second analog value of ADC bit values 603. A third conversion sub-cycle may be referred to as conversion sub-cycle 9 during which the second analog value from conversion sub-cycle 10 is supplied to the comparator. The comparator can perform a comparison and output a result to the SAR ADC to be stored as a 1/0 as shown in table 600 under comparator values 602. Additionally, at conversion sub-cycle 9, the CDAC generates a third analog value of ADC bit values 603. A fourth conversion sub-cycle may be referred to as conversion sub-cycle 8 during which the third analog value from conversion sub-cycle 9 is supplied to the comparator. The comparator can perform a comparison and output a result to the SAR ADC to be stored as a 1/0 as shown in table 600 under comparator values 602. At conversion sub-cycle 8, the CDAC generates a fourth analog value of ADC bit values 603. A fifth conversion sub-cycle may be referred to as conversion sub-cycle 7 during which the fourth analog value from conversion sub-cycle 8 is supplied to the comparator. The comparator can perform a comparison and output a result to the SAR ADC to be stored as a 1/0 as shown in table 600 under comparator values 602. At conversion sub-cycle 7, the CDAC generates a fifth analog value of ADC bit values 603.

Following the first five conversion sub-cycles, the SAR ADC can perform an error-correction sub-cycle denoted by “Conversion sub-cycle DEC1,” during which the SAR ADC can perform noise correction operations with an accuracy of up to 64 least-significant-bits (LSBs) of data processed during conversion sub-cycles 11 through 7.

After the error-correction sub-cycle, the SAR ADC performs a sixth conversion sub-cycle referred to as conversion sub-cycle 6 during which the fifth analog value from conversion sub-cycle 7 is supplied to the comparator. The comparator can perform a comparison and output a result to the SAR ADC to be stored as a 1/0 as shown in table 600 under comparator values 602. At conversion sub-cycle 6, the CDAC generates a sixth analog value of ADC bit values 603. A seventh conversion sub-cycle may be referred to as conversion sub-cycle 5 during which the sixth analog value from conversion sub-cycle 6 is supplied to the comparator. The comparator can perform a comparison and output a result to the SAR ADC to be stored as a 1/0 as shown in table 600 under comparator values 602. At conversion sub-cycle 5, the CDAC generates a seventh analog value of ADC bit values 603. An eighth conversion sub-cycle may be referred to as conversion sub-cycle 4 during which the seventh analog value from conversion sub-cycle 5 is supplied to the comparator. The comparator can perform a comparison and output a result to the SAR ADC to be stored as a 1/0 as shown in table 600 under comparator values 602. At conversion sub-cycle 4, the CDAC generates an eighth analog value of ADC bit values 603.

Following conversion sub-cycles 6 through 4, the SAR ADC can perform another error-correction sub-cycle denoted by “Conversion sub-cycle DEC0,” during which the SAR ADC can perform noise correction operations with an accuracy of up to 8 LSBs of data processing during conversion sub-cycles 6 through 4. At this point, the SAR ADC may also output an ADC bit value 603, denoted by “CP_DIS=1,” that can be provided to clock gating circuitry (e.g., clock gating circuitry 215) to gate a system clock signal (e.g., system clock signal 103) from being provided to a charge pump (e.g., charge pump circuitry 115). When the charge pump does not receive the system clock signal, the charge pump stops producing supplemental power that powers elements of the CDAC of the system, and thus, reduces noise from affecting performance of the SAR ADC.

After the second error-correction sub-cycle, the SAR ADC performs the final conversion sub-cycles before calculating the ADC value output as the digital output signal. A ninth conversion sub-cycle may be referred to as conversion sub-cycle 3 during which the eighth analog value from conversion sub-cycle 4 is supplied to the comparator. The comparator can perform a comparison and output a result to the SAR ADC to be stored as a 1/0 as shown in table 600 under comparator values 602. At conversion sub-cycle 3, the CDAC generates a ninth analog value of ADC bit values 603. A tenth conversion sub-cycle may be referred to as conversion sub-cycle 2 during which the ninth analog value from conversion sub-cycle 3 is supplied to the comparator. The comparator can perform a comparison and output a result to the SAR ADC to be stored as a 1/0 as shown in table 600 under comparator values 602. At conversion sub-cycle 2, the CDAC generates a tenth analog value of ADC bit values 603 An eleventh conversion sub-cycle may be referred to as conversion sub-cycle 1 during which the tenth analog value from conversion sub-cycle 2 is supplied to the comparator. The comparator can perform a comparison and output a result to the SAR ADC to be stored as a 1/0 as shown in table 600 under comparator values 602. At conversion sub-cycle 1, the CDAC generates an eleventh analog value of ADC bit values 603. Finally, a twelfth conversion sub-cycle may be referred to as conversion sub-cycle 0 during which the eleventh analog value from conversion sub-cycle 1 is supplied to the comparator. The comparator can perform a comparison and output a result to the SAR ADC to be stored as a 1/0 as shown in table 600 under comparator values 602.

Following these sub-cycles, the SAR ADC can determine the bit values corresponding to a digital output signal converted from the analog input signal provided to the SAR ADC. Additionally, at this point, the SAR ADC may output an ADC bit value 603, denoted by “CP_DIS=0,” that can be provided to the clock gating circuitry to enable the charge pump, or in other words, allow the system clock signal to be provided to the charge pump. In this way, the charge pump can recalibrate and supply supplemental power to elements of the system and conversion sub-cycles 601 may repeat.

FIG. 7 illustrates an example capacitive digital-to-analog converter (CDAC) circuit used in an implementation. FIG. 7 shows CDAC 700, which includes various switches and capacitors, and is configured to couple to analog input circuitry 110, comparator 214, SAR circuitry 216, and to a power supply.

In various embodiments, CDAC 700 may be representative of a DAC capable of generating binary weighted voltages based on various inputs and providing the generated voltages as inputs to comparator 214 as part of sampling and conversion operations. More specifically, CDAC 700 may include a set of switches configured to couple to analog input circuitry 110, to a power supply, and to SAR circuitry 216. The set of switches includes switches 710, 711, 712, 713, 714, 715, 716, 717, 718, 719, 720, 721, 722, 723, and 724. Each of the switches may include a three-way switch. A first leg of the switches may be configured to couple to analog input circuitry 110 to receive analog input signal 111. A second leg of the switches may be configured to couple to the power supply to receive reference voltage 201 (e.g., a high reference voltage (V_{REFH})). A third leg of the switches may be configured to couple to the power supply to receive reference voltage 202 (e.g., a low reference voltage relative to reference voltage 201 (V_{REFL})). Each switch may further be configured to couple to SAR circuitry 216, which may control the operation of the switches such that the switch can change states and be coupled to receive one of the aforementioned inputs.

The switches may also be coupled to respective ones of a set of capacitors. The set of capacitors includes capacitors 730, 731, 732, 733, 734, 735, 736, 737, 738, 739, 741, 742, 743, 744, 745, 747, 748, and 749. Each capacitor may include two terminals, one of which may be coupled to respective switches, and the other of which may be coupled to other capacitors and to comparator 214. In this example, switch 710 may be coupled to capacitor 730, switch 711 may be coupled to capacitor 731, switch 712 may be coupled to capacitor 732, switch 713 may be coupled to capacitor 733, switch 714 may be coupled to capacitor 734, switch 715 may be coupled to capacitor 735, switch 716 may be coupled to capacitor 736, switch 717 may be coupled to capacitor 737, switch 718 may be coupled to capacitor 738, switch 719 may be coupled to capacitor 741, switch 720 may be coupled to capacitor 742, switch 721 may be coupled to capacitor 743, switch 722 may be coupled to capacitor 744, switch 723 may be coupled to capacitor 745, switch 726 may be coupled to capacitor 747, switch 725 may be coupled to capacitor 748, and switch 724 may be coupled to capacitor 749. CDAC 700 may also include capacitors 740 and 746 coupled between sections of CDAC 700. For example, second terminals of capacitors 730-738 may be coupled to a first terminal of capacitor 740, and second terminals of capacitors 741-746 may be coupled to a second terminal of capacitor 740. Similarly, a second terminal of capacitor 746 may be coupled to second terminals of capacitors 747-749. In various examples, the capacitors may include a capacitance value, some different from each other, some the same as others.

In operation, SAR circuitry 216 may control one switch of CDAC 700 at a time per sampling or conversion sub-cycle, such that one switch may receive a reference input of one among analog input signal 111, reference voltage 201, or reference voltage 202, generate analog input 213 as a function of the reference input and an input provided to the switch by SAR circuitry 216 (e.g., digital value 218), and output analog input 213 as an input to comparator 214. During sampling operations, SAR circuitry 216 may control switches of CDAC 700 to be coupled to receive analog input signal 111 from analog input circuitry 110. During conversion operations, SAR circuitry 216 may control switches of CDAC 700 to be coupled to receive either reference voltage 201 or reference voltage 202 based on an output of comparator 214 and supplied to CDAC 700 by SAR circuitry 216.

By way of example, and in reference to FIG. 6, during conversion sub-cycle 11, SAR circuitry 216 may be configured to control switch 710 such that capacitor 730 couples to the power supply and receives reference voltage 201. Other switches may remain in an open state during this sub-cycle. CDAC 700 can generate analog input 213 including a binary weighted voltage based on reference voltage 201 and output analog input 213 to comparator 214. Comparator 214 may be configured to compare the voltage value of analog input 213 to common mode voltage 203 and provide an output voltage to SAR circuitry 216. Following sub-cycle 11, SAR circuitry 216 may open switch 710. Based on the output of comparator 214 indicating a high value, SAR circuitry 216 may be configured to control switch 711, during conversion sub-cycle 10, such that capacitor 731 couples to the power supply and receives reference voltage 201. However, based on the output of comparator 214 indicating a low value, SAR circuitry 216 may be configured to control switch 711, during conversion sub-cycle 10, such that capacitor 731 couples to the power supply and receives reference voltage 202. In this way, a given switch and capacitor may be used for each conversion sub-cycle and coupled to receive one of reference voltage 201 or 202 to generate a value for analog input 213 for comparison by comparator 214 based on the outputs of comparator 214. It follows that for conversion sub-cycle 9, SAR circuitry 216 may control operation of switch 712, such that a voltage is supplied to capacitor 732 to generate the value of analog input 213 for comparison during the conversion sub-cycle. This process may continue for each sub-cycle using a subsequent switch and capacitor to determine a sequence of bits for a digital signal based on a selected analog input signal 111.

FIG. 8 illustrates an example series of steps of controlling a charge pump circuit to reduce asynchronous noise in a system in an implementation. FIG. 8 includes operations 800, which reference elements of FIGS. 1 and 2. Operations 800 may include steps for performing sampling and conversion functions and controlling a charge pump circuit during the sampling and conversion functions. Operations 800 may be performed via one or more circuits, such as those of systems 100 and 200.

In operation 805, signal conversion circuitry 120 receives one of analog input signals 101 for conversion to a digital output signal during a conversion cycle. Signal conversion circuitry 120 may be representative of an analog-to-digital converter (ADC) capable of receiving analog input signals 101 from analog input circuitry 110 and converting analog input signals 101 to digital output signals 106 based on conversion clock signal 105 and by using the supplemental power generated by charge pump circuitry 115. In various examples, signal conversion circuitry 120 includes a capacitive digital-to-analog converter (CDAC), a comparator, and a successive-approximation register (SAR) ADC, among other components. Together, these components can sample values of the analog input signals 105 at a sampling rate based on conversion clock signal 105 to produce digital output signals 106.

Analog input circuitry 110 may provide the analog input signal to signal conversion circuitry 101 in response to receiving channel selection input 102 indicating the analog input signal. In various examples, analog input circuitry 110 includes a multiplexer configured to select the analog input signal among a plurality of analog input signals 101 based on channel selection input 102. Channel selection input 102 may be provided to analog input circuitry 110 by a circuit, a processor (e.g., a central processing unit (CPU)), or by some other peripheral.

In operation 810, signal conversion circuitry 120 and analog input circuitry 110 receive supplemental power from charge pump circuitry 115. Charge pump circuitry 115 may be representative of a circuit capable of receiving system clock signal 103 and input power 104 and producing a supplemental power based on system clock signal 103 and input power 104 that may have a higher voltage than input power 104. For example, input power 104 may be a power supply voltage of system 100, which has a voltage value of approximately 1.35 V, and system clock signal 103 may be a clock signal used by various elements of system 100, which has a frequency value of 32 MHz during run-time operation of system 100. Charge pump circuitry 115 can operate according to system clock signal 103 and produce a supplemental power having a voltage value of approximately 3 V. Charge pump circuitry 115 can supply this supplemental power to analog input circuitry 110 to power elements of analog input circuitry 110 and signal conversion circuitry 120.

In operation 815, signal conversion circuitry 120 converts the analog input signal to the digital output signal over iterations of the conversion cycle. The conversion cycle may be based on conversion clock signal 105, which may be provided to signal conversion circuitry 120 via clock generator circuitry 220. In an example, signal conversion circuitry 120 is representative of a 12-bit ADC configured to operate with a sampling rate of 4 Megasamples per second (MSPS). Accordingly, conversion clock signal 105 may include a clock signal having a frequency of approximately 80 MHz. Based on this sampling rate, signal conversion circuitry 120 may be configured to perform a single conversion cycle in approximately 250 ns. A conversion cycle may include a sampling period and a conversion period. The conversion period may have 14 sub-cycles, which include 12 sub-cycles based on 12 bits and 2 error-correction sub-cycles. The 2 error-correction sub-cycles may be included to perform noise correction operations. Signal conversion circuitry 120 may be configured to perform the sampling period in approximately 62.5 ns and the conversion period in approximately 187.5 ns.

In operation 820, during each iteration of the conversion cycle, signal conversion circuitry 120 may be configured to control charge pump circuitry 115 based on a state of the conversion cycle. More specifically, SAR circuitry 216 of signal conversion circuitry 120 may be configured to provide control signals 217 to clock gating circuitry 215 to disable or enable charge pump circuitry 115, such as by gating system clock signal 103 from being provided to charge pump circuitry 115. For example, based on a first state of the conversion cycle, SAR circuitry 216 can provide control signals 217 having a first value indicative of a logical high state to clock gating circuitry 215. Based on control signals 217 including a logical high value, clock gating circuitry 215 can provide system clock signal 103 to charge pump circuitry 115 to enable operation thereof. Based on a second state of the conversion cycle, SAR circuitry 216 can provide control signals 217 having a second value indicative of a logical low state to clock gating circuitry 215. Based on control signals 217 including a logical low value, clock gating circuitry 215 can gate system clock signal 103, such that charge pump circuitry 115 does not receive system clock signal 103, and thus, does not produce recalibrated supplemental power for analog input circuitry 110 and signal conversion circuitry 120.

To control charge pump circuitry 115, SAR circuitry 216 may be configured to identify a count of clock cycles of conversion clock signal 105 during the conversion cycle, determine that the count of clock cycles exceeds a threshold clock cycle, and in response to determining that the count of clock cycles exceeds the threshold clock cycle, disable charge pump circuitry 115 via control signals 217 provided to clock gating circuitry 215. Following the example above where the conversion cycle includes 14 sub-cycles during a conversion period, the threshold clock cycle may be determined as a sub-cycle immediately following a second one of the error-correction sub-cycles. The remaining portion of sub-cycles following this error-correction sub-cycle may include functional sub-cycles at the end of the conversion period (e.g., sub-cycles 3 to 0). Accordingly, SAR circuitry 216 may be configured to disable charge pump circuitry 115 in response to detecting that SAR circuitry 216 is in a non-correction state of a conversion cycle (i.e., conversion clock signal 105 has reached a number of cycles corresponding to a non-correction state) by providing control signals 217 to clock gating circuitry 215 that causes clock gating circuitry 215 to gate system clock signal 103 from being provided to charge pump circuitry 115. Following completion of a conversion cycle and/or at the initiation of a subsequent conversion cycle, SAR circuitry 216 may be configured to enable, or re-enable, charge pump circuitry 115, such as by outputting control signals 217 with a different value to clock gating circuitry 215, which causes clock gating circuitry 215 to provide system clock signal 103 to charge pump circuitry 115.

While some examples provided herein are described in the context of a digital signal processing system, sampling and conversion circuitry, power circuitry, clock generation circuitry, an embedded system or system-on-chip, sub-circuit, system, subsystem, component, device, architecture, or environment, it should be understood that the circuits, devices, logic elements, and other components, systems, and methods described herein are not limited to such embodiments and may apply to a variety of other processes, systems, applications, devices, and the like, such as other circuits, logic devices, transistors, and the like, in the context of sampling and conversion functionality, for example. Accordingly, aspects of the present invention may be embodied as other systems, methods, and other configurable systems.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A system, comprising:
analog input circuitry configured to supply an analog input signal to signal conversion circuitry;
charge pump circuitry configured to supply a supplemental power to the analog input circuitry; and
the signal conversion circuitry configured to, during each iteration of a conversion cycle:
convert the analog input signal to a digital output signal; and
control the charge pump circuitry based on a state of the conversion cycle.

2. The system of claim 1, wherein the conversion cycle comprises a set of conversion sub-cycles, and wherein, to control the charge pump circuitry, the signal conversion circuitry is configured to disable the charge pump circuitry during a first portion of the set of conversion sub-cycles and enable the charge pump circuitry during a second portion of the set of conversion sub-cycles.

3. The system of claim 1, wherein to control the charge pump circuitry, the signal conversion circuitry is configured to:
identify a count of clock cycles during the conversion cycle;
determine that the count of clock cycles exceeds a threshold clock cycle; and
in response to determining that the count of clock cycles exceeds the threshold clock cycle, disable the charge pump circuitry.

4. The system of claim 1, wherein to convert the analog input signal to the digital output signal, the signal conversion circuitry is configured to sample the analog input signal using a first clock signal.

5. The system of claim 4, wherein to supply the supplemental power to the analog input circuitry, the charge pump circuitry is configured to produce the supplemental power using a second clock signal.

6. The system of claim 5, wherein the first clock signal differs from the second clock signal.

7. The system of claim 6, further comprising clock gating circuitry coupled to the charge pump circuitry, wherein to control the charge pump circuitry, the signal conversion circuitry is configured to gate the second clock signal to the charge pump circuitry via the clock gating circuitry.

8. A system, comprising:
analog input circuitry configured to supply an analog input signal to signal conversion circuitry;
charge pump circuitry configured to supply a supplemental power to the analog input circuitry; and
the signal conversion circuitry comprising:
a digital-to-analog converter coupled to receive the analog input from the analog input circuitry;
a comparator coupled to the digital-to-analog converter; and
a successive-approximation-register converter coupled to the digital-to-analog converter and to the comparator;
wherein the signal conversion circuitry is configured to, during each iteration of a conversion cycle:
convert the analog input signal to a digital output signal; and
control the charge pump circuitry based on a state of the conversion cycle.

9. The system of claim 8, wherein the conversion cycle comprises a set of conversion sub-cycles, and wherein, to control the charge pump circuitry, the signal conversion circuitry is configured to disable the charge pump circuitry during a first portion of the set of conversion sub-cycles and enable the charge pump circuitry during a second portion of the set of conversion sub-cycles.

10. The system of claim 8, wherein to control the charge pump circuitry, the signal conversion circuitry is configured to:
identify a count of clock cycles during the conversion cycle;
determine that the count of clock cycles exceeds a threshold clock cycle; and
in response to determining that the count of clock cycles exceeds the threshold clock cycle, disable the charge pump circuitry.

11. The system of claim 8, wherein to convert the analog input signal to the digital output signal, the signal conversion circuitry is configured to sample the analog input signal using a first clock signal.

12. The system of claim 11, wherein to supply the supplemental power to the analog input circuitry, the charge pump circuitry is configured to produce the supplemental power using a second clock signal.

13. The system of claim 12, wherein the first clock signal differs from the second clock signal.

14. The system of claim 13, further comprising clock gating circuitry coupled to the charge pump circuitry, wherein to control the charge pump circuitry, the signal conversion circuitry is configured to gate the second clock signal to the charge pump circuitry via the clock gating circuitry.

15. A method, comprising:
receiving, via analog input circuitry, an analog input signal for conversion to a digital output signal during a conversion cycle;
supplying, via charge pump circuitry, supplemental power to the analog input circuitry; and
during each iteration of the conversion cycle:
converting, via signal conversion circuitry, the analog input signal to the digital output signal; and
controlling, via the signal conversion circuitry, the charge pump circuitry based on a state of the conversion cycle.

16. The method of claim 15, wherein the conversion cycle comprises a set of conversion sub-cycles, and wherein, controlling the charge pump circuitry comprises disabling the charge pump circuitry during a first portion of the set of conversion sub-cycles and enabling the charge pump circuitry during a second portion of the set of conversion sub-cycles.

17. The method of claim 15, wherein controlling the charge pump circuitry comprises:
identifying a count of clock cycles during the conversion cycle;
determining that the count of clock cycles exceeds a threshold clock cycle; and
in response to determining that the count of clock cycles exceeds the threshold clock cycle, disabling the charge pump circuitry.

18. The method of claim 15, wherein converting the analog input signal to the digital output signal comprises sampling the analog input signal using a first clock signal.

19. The method of claim 18, wherein supplying the supplemental power to the analog input circuitry comprises producing the supplemental power using a second clock signal.

20. The method of claim 19, wherein the first clock signal differs from the second clock signal.
